(19) United States
(12) Patent Application Publication
(10) Pub. No.: US 2024/0120186 A1
(43) Pub. Date: Apr. 11, 2024

(54) PLASMA HYPERMODEL INTEGRATED WITH FEATURE-SCALE PROFILE MODEL FOR ACCELERATED ETCH PROCESS DEVELOPMENT

(71) Applicant: KLA CORPORATION, Milpitas, CA (US)

(72) Inventors: Chad HUARD, Austin, TX (US); Premkumar PANNEERCHELVAM, Austin, TX (US); Shuo HUANG, Ann Arbor, MI (US); Mark D. SMITH, San Jose, CA (US)

(21) Appl. No.: 17/982,472

(22) Filed: Nov. 7, 2022

Related U.S. Application Data
(60) Provisional application No. 63/414,603, filed on Oct. 10, 2022.

(51) Int. Cl. H01J 37/32

(52) U.S. Cl. CPC H01J 37/32935; H01J 37/32715; H01J 2237/334

(57) ABSTRACT

Plasma parameters at a surface of a wafer are determined with a plasma hypermodel based on plasma processing conditions. A post-processing profile can be predicted for the surface of the wafer with a feature-scale profile model. Correlations in the plasma hypermodel can be recalibrated if the post-processing profile is outside a convergence criterion of an experimental reference.

### CROSS-REFERENCE TO RELATED APPLICATIONS

This application claims priority to the provisional patent application filed Oct. 10, 2022 and assigned U.S. App. No. 63/414,603, the disclosure of which is hereby incorporated by reference.

### FIELD OF THE DISCLOSURE

This disclosure relates to semiconductor manufacturing.

### BACKGROUND OF THE DISCLOSURE

Fabricating semiconductor devices, such as logic and memory devices, typically includes processing a semiconductor wafer using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etching, deposition, and ion implantation. An arrangement of multiple semiconductor devices fabricated on a single semiconductor wafer may be separated into individual semiconductor devices.

Many of these fabrication processes use a plasma. For example, plasma etching, ion implantation, and plasma-enhanced chemical vapor deposition (PECVD) all generate a plasma as part of their operations. The operational settings for these processes can be based on a simulation of the plasma parameters.

In a previous method, a rigorous physics-based plasma model was used to simulate the plasma in an etch reactor to obtain the plasma parameters at the wafer surface, such as radical fluxes and ion energies. These plasma parameters were then imported into a feature-scale profile model to predict the resulting etch profiles. This previous method used two separated models, the rigorous physics-based plasma model and a feature-scale profile model, which were executed in tandem. Each model was separately calibrated, and the data was manually transported from the plasma model to the profile model. There was little communication or interaction between the rigorous physics-based plasma model and the feature-scale profile model beyond this manual transport. The surface chemistry in the feature-scale profile model and the plasma chemistry in the rigorous physics-based plasma model could not be co-optimized. It also was impossible for numerical algorithms to be implemented to calibrate the two separate models. Consequently, the iterative approach to loop between the two models for calibration was time-consuming and inefficient.

Therefore, new techniques and systems are needed.

### BRIEF SUMMARY OF THE DISCLOSURE

A method is provided in a first embodiment. The method includes receiving plasma process conditions at a processor and determining, using the processor, plasma parameters at a surface of a wafer based on the plasma processing conditions with a plasma hypermodel. The plasma process conditions can include one or more of pressure, gas chemistry, temperature, flow rate, source power, bias power, source power, or a pulse condition.

The method can further include inputting the plasma parameters into a feature-scale profile model and predicting, using the processor, a post-processing profile for the surface of the wafer with the feature-scale profile model. The post-processing profile can be compared with an experimental reference using the processor. Correlations in the plasma hypermodel can be recalibrated using the processor if the post-processing profile is outside a convergence criterion of the experimental reference. The experimental reference can be a TEM image or an XSEM image.

The plasma hypermodel can include a matrix that is multiplied by the plasma process conditions.

The plasma conditions can be for an etch process, a deposition process, or an ion implant process.

The method can further exposing the wafer to a plasma with the plasma process conditions in a plasma processing tool.

A non-transitory computer readable medium storing a program can be configured to instruct the processor to execute the method of the first embodiment.

A system is provided in the second embodiment. The system includes a plasma processing tool having a plasma chamber; a stage disposed in the plasma chamber configured to hold a wafer; and a plasma generation system. The plasma processing tool can be an etch tool, a deposition tool, or an ion implant tool. A processor is in electronic communication with the plasma processing tool. The processor is configured to receive plasma process conditions and determine plasma parameters at a surface of the wafer based on the plasma processing conditions with a plasma hypermodel. The plasma process conditions can include one or more of pressure, gas chemistry, temperature, flow rate, source power, bias power, source power, or a pulse condition.

The processor can be further configured to input the plasma parameters into a feature-scale profile model and predict a post-processing profile for the surface of the wafer with the feature-scale profile model. The processor can be configured to compare the post-processing profile with an experimental reference. The processor also can be configured to recalibrate correlations in the plasma hypermodel if the post-processing profile is outside a convergence criterion of the experimental reference. The experimental reference can be a TEM image or an XSEM image.

The plasma hypermodel can include a matrix that is multiplied by the plasma process conditions.

The processor can be configured to send instructions to the plasma processing tool to generate a plasma with the plasma process conditions.

### DESCRIPTION OF THE DRAWINGS

For a fuller understanding of the nature and objects of the disclosure, reference should be made to the following detailed description taken in conjunction with the accompanying drawings, in which:

FIG. 1 is a flowchart of an embodiment of a calibration process based on the integration of plasma hypermodel and feature-scale profile model in accordance with the present disclosure;

FIG. 2 is a block diagram of an exemplary system in accordance with the present disclosure; and

FIG. 3 shows contours of the correlations in an Ar/Cl₂ plasma hypermodel between the process conditions (power and pressure) and plasma parameters at wafer surface that are calibrated based on XSEM images from different process conditions.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

In the embodiments disclosed herein, a plasma hypermodel is integrated with a feature-scale profile model for process development. Based on the process conditions, the plasma hypermodel generates plasma parameters at wafer surface, which are then used as the inputs for the feature-scale profile model to predict a feature profile. Thus, the plasma hypermodel and the feature-scale profile model can be co-optimized. The integration of the plasma hypermodel and the feature-scale profile model can enable the model calibration and process optimization from macroscopic process conditions such as power and pressure to microscopic feature metrics such as critical dimensions and sidewall angles.

The plasma hypermodel has tunable parameters instead of the large sets of fixed parameters in rigorous physics-based plasma model. With the integration of the plasma hypermodel and the feature-scale profile model, a metrology reference can be used to calibrate both the plasma hypermodel and feature-scale profile model through numerical algorithms based on the experimental references such as transmission electron microscopy (TEM) and cross-sectional scanning electron microscope (XSEM) images. The TEM and XSEM images are easier to access compared to plasma parameters at the surface during the operation of the plasma reactor. Once calibrated, the plasma hypermodel and the feature-scale profile model can be used to predict profiles for other process conditions. The plasma hypermodel can capture both linear and nonlinear relations between reactor knobs (e.g., power and pressure) in different forms (e.g., first-order, second-order, or cross term) and plasma parameters at wafer surface (e.g., energy and flux).

The process development of computational models depends on the accuracy and efficiency of the models. High-fidelity and high-efficiency models with process conditions tuned by the knobs on the process reactor as the inputs and predicted feature profiles as the outputs can improve high-volume manufacturing.

In a previous method to achieve high-fidelity and high-efficiency models, both reactor scale modeling and feature scale modeling were used in tandem. For the reactor-scale plasma modeling that is used to model the plasmas in the etch reactor using rigorous physics-based approaches, the process conditions tuned by the knobs on the reactor (e.g., power and pressure) were the inputs. The physics equations for transport, kinetics, and electromagnetics and the chemical reactions for gas phase reactions and surface reactions were solved. The outputs were the plasma parameters (e.g., flux and energy) at the wafer surface. For the feature-scale profile modeling used to model the feature profile evolution with rigorous physics-based approaches, the outputs of reactor scale modeling, which are the plasma parameters, are used as the inputs. The transport and surface reactions of the plasma particles were modeled with the consequent etch feature profile as the outputs.

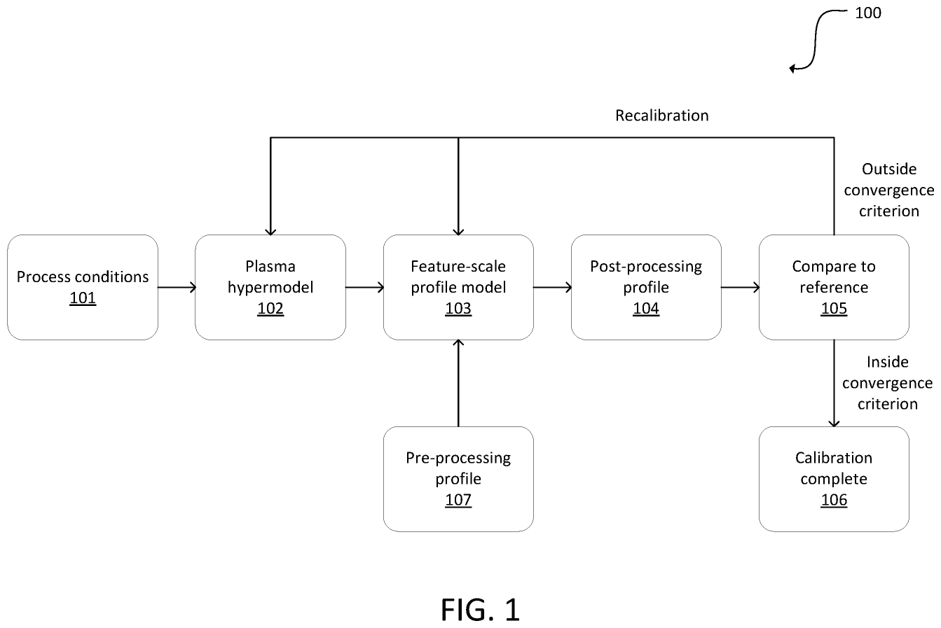

As disclosed herein, a plasma hypermodel is used instead of the reactor-scale plasma modeling to correlate the process conditions to the plasma parameters at the wafer surface. The correlations are based on empirical assumptions. Their coefficients can be calibrated based on cost functions defined by the difference between modeling results and experimental references. The plasma hypermodel is integrated with a rigorous physics-based profile model for model calibration. The iterative regression approach for calibration is shown in the method 100 of FIG. 1. With the process conditions as the inputs, the plasma hypermodel generates the plasma parameters at the wafer surface based on the correlations included in it. Those plasma parameters can be used as the inputs of the subsequent feature-scale model to predict the post-processing profiles (e.g., post-etch profiles). A cost function based on the difference between the model predicted profiles and the experimental references (e.g., TEM or XSEM images) can be evaluated. If the evaluation result satisfies the pre-set convergence criterion, then the model calibration is completed and can be used for process optimizations. If the evaluation result fails the convergence criterion, then a numerical algorithm can be used to re-calibrate both the correlations in the plasma hypermodel and the transport and surface reactions in the feature-scale profile model. This process can repeat until the predicted feature profiles from the plasma hypermodel and the feature-scale profile model satisfy the convergence criterion.

A hypermodel refers to correlations or mapping between two sets of data (i.e., input data and output data) or multiple sets of data. The input data can be the control knobs of a physical system (e.g., a plasma processing tool like a plasma etch tool) and the output data is the parameters that the engineers would like to control (e.g., plasma flux, ion energy, temperature) through the control knobs. The hypermodel can be one matrix or several matrix multiplied together.

Compared with the previous method that may only allow a process engineer to iterate on plasma recipes on a weekly basis, the embodiments disclosed herein can allow a process engineer to iterate on their plasma recipe more frequently. For example, the plasma recipe can be iterated on a daily basis using the embodiments disclosed herein. The previous method needed both rigorous physics-based plasma modeling, which usually took several days to finish, and rigorous physics-based etch modeling. The process engineer would manually transfer the outputs of plasma modeling into the etch modeling as the inputs. Embodiments disclosed herein use a plasma hypermodel, which can take less than a second to finish, to replace the rigorous physics-based plasma modeling. The flow shown in FIG. 1 can automate the calibration process for both the plasma hypermodel and rigorous physics-based modeling in the feature-scale profile model, so the efficiency is improved and a process engineer can iterate a recipe for optimal profile control on a daily basis rather than weekly basis.

In the plasma hypermodel, a matrix operator, A, is assumed to correlate the process conditions, x, to plasma parameters at wafer surface, y, with an adjustable bias, b, in the form of y=Ax+b. These correlations can be, for example, filled in the following form.

$$[ \begin{matrix}Flux 1 \\ Flux 2 \\ Energy of Ion 1 \\ Energy of Ion 2 \\ Angle of Ion 1 \\ Angle of Ion 2 \\ …\end{matrix} ] = [ \begin{matrix}{a}_{11} & … & {a}_{1 m} \\ ⋮ & ⋱ & ⋮ \\ {a}_{n 1} & … & {a}_{nm}\end{matrix} ] [ \begin{matrix}Flow rate of Gas 1 \\ Flow rate of Gas 2 \\ Pressure \\ Power \\ Pulse frequency \\ Duty cycle \\ …\end{matrix} ] + [ \begin{matrix}{b}_{1} \\ ⋮ \\ {b}_{n}\end{matrix} ]$$

The above equation shows first order form of vector x, which can also have the following cross-term form.

$$[ \begin{matrix}Power \times Duty cycle \\ Flow rate of Gas 1 \times Flow rateof Gas 2 \\ Flow rate of Gas 1 / Flow rate of Gas 2 \\ …\end{matrix} ]$$

The vector x also can have the following second order form.

$$[ \begin{matrix}{Pressure}^{2} \\ {Power}^{0.5} \\ …\end{matrix} ]$$

The vector x also can have a combination of first order, second order, and cross terms as shown below.

$$[ \begin{matrix}Pulse frequency \\ Power \times Duty cycle \\ Flow rate of Gas 1 / Flow rate of Gas 2 \\ {Pressure}^{2} \\ {Power}^{0.5} \\ …\end{matrix} ]$$

The coefficients in matrix A and vector b can be tuned to get the plasma parameters the result in simulated etch profiles matching the experimental reference. After matrix A and vector b in the plasma hypermodel and the transport and surface reactions in the feature-scale profile model are calibrated, these can be used to predict other process conditions' profiles. The calibrated plasma hypermodel and feature-scale profile model can be used inversely to search for the optimal process conditions based on desirable feature profiles.

The hypermodel correlates input parameters, which are usually different physics parameters (power, pressure, frequency, temperature, etc.) with different physical units and different order of magnitudes and ranges of values. For example, power can be from 1 W to 10000 W and frequency can be from 1 kHz to 100 MHz. The output parameters are different in units, magnitudes (e.g., plasma flux can be from 1015 cm⁻²s⁻¹ to 1018 cm⁻²s⁻¹, ion energy can be from 10 eV to 10000 eV). Given those differences in units, magnitudes, and ranges for both input parameters and output parameters, it can be difficult to efficiently perform calculations using the hypermodel or calibrate the hypermodel without use of a processor.

As shown in FIG. 1, plasma process conditions are received at a processor at 101. The plasma process conditions can include, for example, one or more of pressure, gas chemistry, temperature, flow rate, source power, bias power, source power, a pulse condition (e.g., pulse frequency or duty cycle of pulse), or other parameters. The processor can determine outputs based on the plasma processing conditions using a plasma hypermodel at 102. In an embodiment, plasma parameters at a surface of a wafer are determined using the plasma hypermodel. The plasma hypermodel can include a matrix that is multiplied by the plasma process conditions.

The plasma parameters determined by the plasma hypermodel can include, for example, one or more of a flux of neutral radicals, a flux of ions, an energy of ions, an angle of ions, or other parameters. For certain plasma processing tools like plasma etch tools with multiple power control knobs, the plasmas may give double-peak or multi-peak distributions for the ions. For these complicated conditions, the hypermodel also can be used to determine the low-energy peak of the ions, high-energy-peak of the ions, flux of the low-energy peak of the ions, and/or flux of the high-energy peak of the ions.

The plasma parameters are inputted into a feature-scale profile model at 103. The feature-scale profile model can be the PROETCH physics-based dry etch simulator from KLA Corporation or other models. The processor can run the feature-scale profile model. The feature-scale profile model can predict a post-processing profile for the surface of the wafer at 103 from the plasma parameters generated by the plasma hypermodel and from a pre-processing profile, which is shown at 105. While disclosed with etching, the method 100 can be applied to other plasma processing techniques such as deposition or ion implantation.

A feature-scale profile model can be used for research or development in semiconductor manufacturing. The feature-scale profile model can be used to develop new technology, new processes or new process flows for new structures, new materials, or a new technology node.

A feature-scale profile model can model the evolution of the features on a semiconductor wafer under exposure to energetic and reactive species generated in the plasma. In an example, the feature-scale profile model can input a hardmask profile and underlying material from a scanning electron microscope (SEM) image or a design file. The feature-scale profile model also can input photoresist profiles and the underlying film stack from a lithography simulator (e.g., PROLITH developed by KLA Corporation). The incoming geometry is discretized as a collection of voxels in 3D space, with each voxel tagged by a material identity. The evolution of this voxel mesh over time due to interactions with the plasma is tracked to predict the post-processing profiles. Other methodologies in the feature-scale profile model are possible and this is merely one example.

As shown in FIG. 1, the processor can compare the post-processing profile with an experimental reference at 105. If the post-processing profile is outside a convergence criterion of the experimental reference, then a recalibration process can be initiated. Correlations for the plasma hypermodel and/or the feature-scale profile model can be adjusted. If the post-processing profile is inside or is inside or equal to the convergence criterion, then the calibration is complete as shown at 106

The convergence criterion can be that the cost is smaller than a user-set threshold. The cost is calculated based on the difference between the feature-scale profile model simulation results and the experimental references. For example, for a bow critical dimension (CD), the experimental reference is 20 nm. The feature-scale profile model gives 25 nm. The cost is calculated as a function of the difference (i.e., 25 nm-20 nm). This difference can be multiplied by one or more factors, such as standard deviation or stochastic noise, as part of the function.

The adjusted parameters in the hypermodel can include, for example, linear coefficients and power coefficients for the correlations assumed between the input parameters and output parameters. The adjusted parameters in the feature-scale profile model can include, for example, the surface reaction parameters (e.g., sticking coefficient, sputter yield, threshold energy, etc.) or the plasma operating conditions (e.g., power, pressure, frequency, temperature, process time, process steps, etch recipes, etc.).

The experimental reference can be, for example, TEMs or XSEMs. In addition to those TEM and XSEM images, other references can be, for example, the critical dimensions at different heights, unique sizes (e.g., neck CD, bow CD, bottom CD, etch depth, mask remaining thickness, etc.), an ideal profile, or a target profile (e.g., straight or anisotropic profile).

If the post-processing profile is within or is within or equal to a convergence criterion of the experimental reference, then the calibration can be complete. The processor can send instructions to expose the wafer to a plasma with the plasma process conditions in a plasma processing tool.

It will be understood that, while a processor for the exemplary features of the method of FIG. 1 have been described, such an arrangement is not to be construed as limiting the invention to such features. The method may be implemented in software, firmware, hardware, or a combination thereof. In one mode, the method is implemented in software, as an executable program, and is executed by one or more special or general purpose digital computer(s), such as a personal computer (e.g., IBM-compatible, Apple-compatible, workstation, or mainframe computer). The steps of the method may be implemented by a server or computer in which the software modules reside or partially reside.

Generally, in terms of hardware architecture, such a computer will include, as will be well understood by the person skilled in the art, a processor, memory, and one or more input and/or output (I/O) devices (or peripherals) that are communicatively coupled via a local interface. The local interface can be, for example, but not limited to, one or more buses or other wired or wireless connections, as is known in the art. The local interface may have additional elements, such as controllers, buffers (caches), drivers, repeaters, and receivers, to enable communications. Further, the local interface may include address, control, and/or data connections to enable appropriate communications among the other computer components.

The processor(s) may be programmed to perform the functions of the embodiments of FIG. 1. The processor(s) is a hardware device for executing software, particularly software stored in memory. Processor(s) can be any custom made or commercially available processor, a primary processing unit (CPU or GPU), an auxiliary processor among several processors associated with a computer, a semiconductor-based microprocessor (in the form of a microchip or chip set), a macro-processor, or generally any device for executing software instructions.

Memory is associated with processor(s) and can include any one or a combination of volatile memory elements (e.g., random access memory (RAM, such as DRAM, SRAM, SDRAM, etc.)) and non-volatile memory elements (e.g., ROM, hard drive, tape, CDROM, etc.). Moreover, memory may incorporate electronic, magnetic, optical, and/or other types of storage media. Memory can have a distributed architecture where various components are situated remote from one another, but are still accessed by processor(s).

The software in memory may include one or more separate programs. The separate programs comprise ordered listings of executable instructions for implementing logical functions in order to implement the functions of the modules. In the example of heretofore described, the software in memory includes the one or more components of the method and is executable on a suitable operating system (O/S).

The present disclosure may include components provided as a source program executable program (object code), script, or any other entity comprising a set of instructions to be performed. When a source program, the program needs to be translated via a compiler, assembler, interpreter, or the like, which may or may not be included within the memory, so as to operate properly in connection with the O/S. Furthermore, a methodology implemented according to the teaching may be expressed as (a) an object-oriented programming language, which has classes of data and methods, or (b) a procedural programming language, which has routines, subroutines, and/or functions, for example but not limited to, C, C++, Pascal, Basic, Fortran, Cobol, Ped, Java, and Ada.

An additional embodiment relates to a non-transitory computer-readable medium storing program instructions executable on a processor for performing a computer-implemented method for calibrating plasma process conditions, as disclosed herein. In particular, an electronic data storage unit or other storage medium may contain non-transitory computer-readable medium that includes program instructions executable on the processor. The computer-implemented method may include any step(s) of any method(s) described herein.

Each of the steps of the method may be performed as described herein. The methods also may include any other step(s) that can be performed by the processor and/or computer subsystem(s) or system(s) described herein. The steps can be performed by one or more computer systems, which may be configured according to any of the embodiments described herein. In addition, the methods described above may be performed by any of the system embodiments described herein.

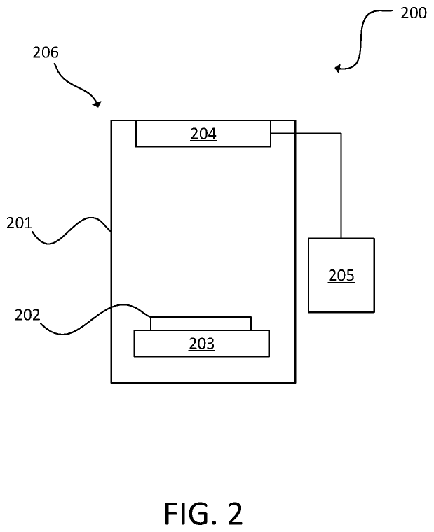

FIG. 2 is a block diagram of a system 200. The system 200 includes a plasma processing tool 206, which has a plasma chamber 201, a stage 203 in the plasma chamber 201 that holds a wafer 202, and a plasma generation system 204. The plasma generation system 204 may be an RF plasma generation system, inductively coupled plasma (ICP) generation system, or other types of ion sources. The plasma processing tool 206 can be an etch tool, a deposition tool, an ion implant tool such as a plasma doping tool, or another plasma processing tool. An ion implant tool that has a beamline with beam optics also can benefit from the embodiments disclosed herein.

A processor 205 is in electronic communication with the plasma generation system 204 or other components of the plasma processing tool 206. The processor 205 is illustrated as a single functional block for ease of illustration, but in practice the processor 205 may comprise multiple, interconnected processors, with suitable interfaces for receiving and outputting the signals that are illustrated in the figures and are described in the text.

The processor 205 may be part of the plasma processing tool 206 or separate from the plasma processing tool 206. For example, the processor 205 may be on a system or other server within a semiconductor manufacturing facility. The processor 205 can be used offline from the plasma processing tool 206.

The processor 205 can be configured to perform some or all the steps of the method of FIG. 1. Thus, the processor 205 can receive plasma process conditions and determine plasma parameters at a surface of the wafer 202 with a plasma hypermodel. The processor 205 also can be configured to input the plasma parameters into a feature-scale profile model and predict a post-processing profile for the surface of the wafer 202 with the feature-scale profile model.

The processor 205 can be configured to compare the post-processing profile with an experimental reference (e.g., a TEM image or an XSEM image). The processor 205 can be configured to recalibrate correlations in the plasma hypermodel if the post-processing profile is outside a convergence criterion of the experimental reference.

If the post-processing profile is within or is within or equal to a convergence criterion then the processor 205 can be optionally configured to send instructions to the plasma processing tool 206 to generate a plasma inside the plasma chamber 201 with the plasma process conditions.

While described with a plasma processing tool, the embodiments disclosed herein can be operated on or with a metrology tool, inspection tool, or review tool. This can include a light-based, ion beam-based, x-ray-based, or electron beam-based system. The ion beam-based imaging subsystem can be a focused ion beam (FIB) system, a helium ion microscopy (HIM) system, or a secondary ion mass spectroscopy (SIMS) system. Such a system can be used to generate images of a test wafer, such as that with the pre-processing profile or the reference used in comparison with the post-processing profile (e.g., pre-etch profiles and post-etch profiles, pre-deposition profiles and post-deposition profiles, or pre-implant profiles and post-implant profiles).

The following examples are presented to illustrate the present disclosure. They are not intended to be limiting.

### Example 1

For a silicon etch process using Ar/Cl₂ plasma, the process conditions include pressure, power, pulse frequency and duty cycle, etc. The plasma parameters at the wafer surface that directly affect etch profile include at least flux, energy, and angle. Empirical correlations between the plasma parameters and the process conditions are assumed as follows.

Ion flux: Fluxᵢₒₙ=a×Pressure+b

Fraction of high energy ion flux: Fraction_{high energy ion}=c×Power+d

Fraction of low energy ion flux: Fraction_{low energy ion}=1−Fraction_{high energy ion}

Radical flux: Flux_{C1}=e×Pressure+f

High ion energy: Energy_{high energy ion}=g×Power+h×Pressure+i

Low ion energy: Energy_{high energy ion}=j×Power+k×Pressure+1

The above equations can be written in the following matrix format.

$$[ \begin{matrix}{Flux}_{ion} \\ {Fraction}_{high energy ion} \\ {Flux}_{Cl} \\ {Energy}_{high energy ion} \\ {Energy}_{high energy ion}\end{matrix} ] = [ \begin{matrix}a & 0 \\ 0 & c \\ e & 0 \\ h & g \\ k & j\end{matrix} ] [ \begin{matrix}Pressure \\ Power\end{matrix} ] + [ \begin{matrix}b \\ d \\ f \\ i \\ l\end{matrix} ]$$

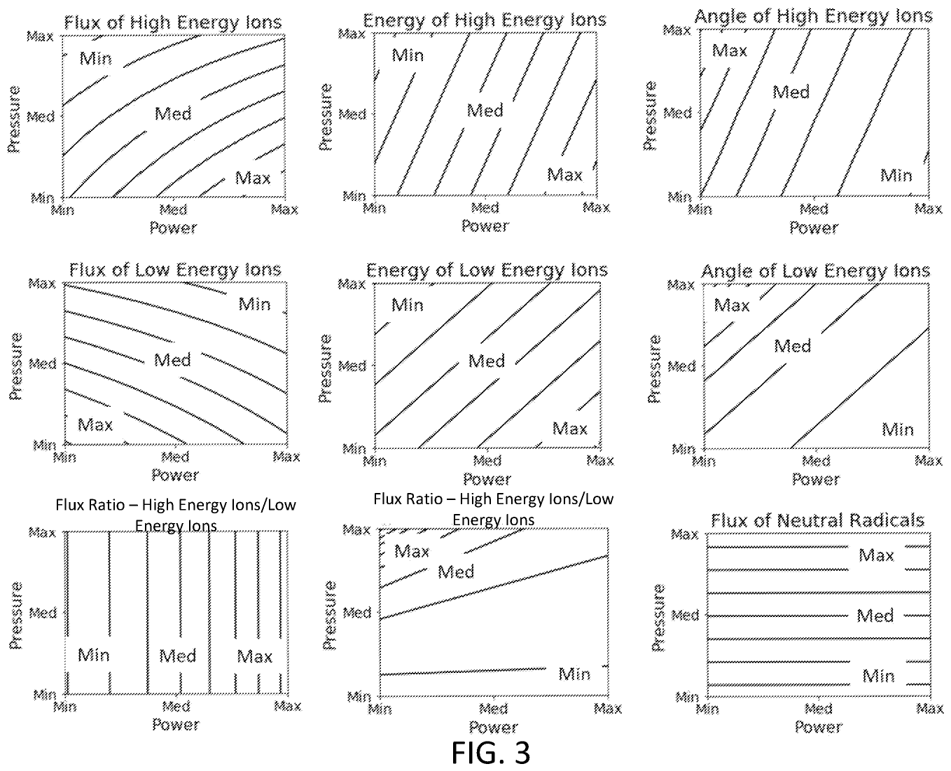

The coefficients in the matrix A and vector b can be tuned to match the experimental references. The contours of the correlations established based on the plasma hypermodel are shown in FIG. 3. These correlations in the Ar/Cl₂ plasma hypermodel were calibrated together with a silicon etch mechanism developed in the feature-scale profile model (PROETCH from KLA Corporation) based on the XSEM images from different process conditions using the iterative approach shown in FIG. 1.

### Example 2

Self-aligned double patterning (SADP) is characterized by performing lithography at a pitch that is two times larger than the desired pitch and is followed by spacer deposition, a spacer etch-back and core etch processes. Double and multiple patterning techniques drive down the technology node with challenges lying at non-uniformity for the spacers.

An example of a feature-scale profile model is PROETCH, which was developed by KLA Corporation. PROETCH is a three-dimensional physics-based plasma dry etch simulator that describes processes occurring during a plasma etch process, including energetic and thermal species propagation through a feature, physical and chemical sputtering of materials, thermal etching, and surface passivation. The inputs can include etch recipe and incoming geometry. The outputs can include a 3D etch profile, feature level local flux distributions, and surface composition. PROETCH can be integrated with PROLITH, a lithography simulator developed by KLA Corporation, for process control.

Silicon can be etched by an Ar/Cl₂ plasma. The surface sites for SADP can include a hardmask (HM), Si, SiCl (lumped passivated surface states), and SiO₂ (stopping layer). The reaction mechanism can include the following.

| | |
|---|---|
| Physical Sputtering of Si | Si(s) + I⁺(g) → Si(g) + I⁺(g) |
| Chlorination of Si | Si(s) + Cl(g) → SiCl(s) |
| Si Thermal Etch | SiCl(s) + Cl(g) → SiCl₄(g) |
| Chemical Sputtering of SiCl | SiCl(s) + I⁺(g) → SiCl(g) + I⁺(g) |
| Sputtering of HM | HM(s) + I⁺(g) → HM(g) + I⁺(g) |
| Redeposition of SiCl | SiCl(g) + HM(s) → SiCl(s) + HM(s) |
| | SiCl(g) + Si(s) → SiCl(s) + Si(s) |
| | SiCl(g) + SiCl(s) → SiCl(s) + SiCl(s) |

For the shallow trench isolation mask, an overlay metrology target in DRAM during shallow trench isolation (STI) etch patterned using SADP was investigated using PROETCH. Each process introduces non-uniformity, leading to variations in, for example, the hardmask that is used for the final etch step to form the gate. The etch profile for specific plasma operating conditions and optimization of the etch process were investigated. During etching of the STI, mask sputtering, bowing, tapered front, and aspect-ratio dependent etching can occur.

In a study, a sensitivity analysis of the model was performed with a parametric study on the mechanism parameters. Physical sputtering mainly contributes to material removal at the bottom and etch front. Chemical sputtering affects both the lateral etch at the sidewall and the vertical etch at the bottom. Chlorination favors the vertical etch as bare sites are converted to SiCl with a lower threshold for removal. The parametric study of plasma parameters (e.g., flux and energy) show the combined effects of multiple reactions involving a specific plasma parameter. Chlorine radicals contribute to chlorination and thermal etch (enhance undercut). Ions contribute to vertical etch and straight profile. Increasing ion energy results in more ions above threshold for both chemical and physical sputtering. Redeposition of etch byproducts can affect direct deposition when etch byproducts are recaptured by the surface without escaping the feature. Redeposition of etch byproducts can affect indirect redeposition after interaction with the gas phase when etch byproducts get out of a feature and are sputtered by the gas phase species back into the feature to deposit. An angular yield curve (dependence of yield on incident ion angle) depends on factors like ion energy, material identity, surface roughness, etc. As incident ion energy increases, an angular yield curve transitions from chemical sputtering-like (peaks at normal incidence) to physical sputtering-like (peaks at 60 degree incidence).

Then a calibration was performed using the method shown in FIG. 1 and described herein. The inputs were the process conditions, pre-processing profiles, and post-processing profiles (e.g., pre-etch profiles and post-etch profiles). The reaction mechanism and plasma hypermodel were calibrated. The cost metrics were the difference between the model-determined profile and experimental profiles. The PROETCH algorithm was used as the feature-scale profile model.

The pre-etch profile can be an SEM image, which can show the hardmask formed by lithography, etching, and/or deposition. While the pre-etch profile can be a real experimental profile, the pre-etch profile also can be a design image (desirable profile).

The plasma hypermodel was used to correlate process conditions (e.g., power, pressure) with plasma parameters (e.g., fluxes, energy). Subset data was used for model calibration. Interpolation and extrapolation of calibrated model were used as validation. A mixture of conditions were chosen to cover wide range of parameters in two dimensions. Both unique sizes and critical dimensions were included in the cost with user-defined weights. Validation was done for conditions other than calibration set. Both interpolation and extrapolation (or hybrid) were used as validation conditions. Validation results matched experimental data well in both unique sizes and critical dimensions.

Process optimization showed forward issues and inverse issues. When looking forward, output performances (e.g., etch rate, profiles, selectivity) could be predicted under certain process conditions (e.g., power, pressure, frequency) by using calibrated model. This can reduce experimental trials and can shorten development cycle. During the inverse, a search for process conditions for optimal etch performances achieved a straight profile, increased throughput, and minimized aspect ratio dependent etch.

With the calibrated model, extrapolating in time domain with fixed etch depth was performed. End point detection (EPD) was used to stop the simulation after the etch front reaches preset depth. CDs and profiles can be visualized to pick up optimal process conditions.

The inversibility of the model can be demonstrated if the process conditions given by the inverse issue converges to the vicinity of the design of experiments (DOE) processes that were conducted to generate the target profiles. Straight profile (uniform CDs) was used as the target/cost for optimizing the process conditions. With different time tolerance, the optimization converges to different conditions. Unique sizes (bow and bottom CDs) were used as the metrics to optimize the process recipe for straight profile. A tolerance window was set to allow the profiles to vary within DOE tolerance range. PROETCH optimized process conditions that close gaps for bottom CD while maintaining bow CD within the tolerance range.

Thus, the rigorous physics based etch model (PROETCH) was developed and validated with STI etch in the SADP process as the use case. A reaction mechanism was developed based on XSEM images of DOE conditions in Si etch by Ar/Cl₂ plasma. A plasma hypermodel based on empirical practice was implemented to correlated process conditions (e.g., power, pressure) with plasma parameters (e.g., fluxes, energy). PROETCH was used in process development to provide etch profiles for conditions which are either interpolated or extrapolated for the DOE ranges and to search for process conditions which can satisfy user-set criterion for optimal etch performances.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A method comprising:
receiving plasma process conditions at a processor; and
determining, using the processor, plasma parameters at a surface of a wafer based on the plasma processing conditions with a plasma hypermodel.

2. The method of claim 1, wherein the plasma process conditions include one or more of pressure, gas chemistry, temperature, flow rate, source power, bias power, source power, or a pulse condition.

3. The method of claim 1, further comprising:
inputting the plasma parameters into a feature-scale profile model; and
predicting, using the processor, a post-processing profile for the surface of the wafer with the feature-scale profile model.

4. The method of claim 3, further comprising comparing, using the processor, the post-processing profile with an experimental reference.

5. The method of claim 4, further comprising recalibrating correlations in the plasma hypermodel using the processor, wherein the post-processing profile is outside a convergence criterion of the experimental reference.

6. The method of claim 4, wherein the experimental reference is a TEM image or an XSEM image.

7. The method of claim 1, wherein the plasma hypermodel includes a matrix that is multiplied by the plasma process conditions.

8. The method of claim 1, wherein the plasma conditions are for an etch process, a deposition process, or an ion implant process.

9. The method of claim 1, further comprising exposing the wafer to a plasma with the plasma process conditions in a plasma processing tool.

10. A non-transitory computer readable medium storing a program configured to instruct the processor to execute the method of claim 1.

11. A system comprising:
a plasma processing tool including:
a plasma chamber;
a stage disposed in the plasma chamber configured to hold a wafer; and
a plasma generation system; and
a processor in electronic communication with the plasma processing tool, wherein the processor is configured to:
receive plasma process conditions; and
determine plasma parameters at a surface of the wafer based on the plasma processing conditions with a plasma hypermodel.

12. The system of claim 11, wherein the plasma processing tool is an etch tool, a deposition tool, or an ion implant tool.

13. The system of claim 11, wherein the plasma process conditions include one or more of pressure, gas chemistry, temperature, flow rate, source power, bias power, source power, or a pulse condition.

14. The system of claim 11, wherein the processor is further configured to:
input the plasma parameters into a feature-scale profile model; and
predict a post-processing profile for the surface of the wafer with the feature-scale profile model.

15. The system of claim 14, wherein the processor is further configured to compare the post-processing profile with an experimental reference.

16. The system of claim 15, wherein the processor is further configured to recalibrate correlations in the plasma hypermodel, wherein the post-processing profile is outside a convergence criterion of the experimental reference.

17. The system of claim 15, wherein the experimental reference is a TEM image or an XSEM image.

18. The system of claim 11, wherein the plasma hypermodel includes a matrix that is multiplied by the plasma process conditions.

19. The system of claim 11, wherein the processor is further configured to send instructions to the plasma processing tool to generate a plasma with the plasma process conditions.
